(19) United States
(12) Patent Application Publication
(10) Pub. No.: US 2026/0188387 A1
(43) Pub. Date: Jul. 2, 2026

(54) MEMORY DEVICE

(71) Applicant: SK hynix Inc., Gyeonggi-do (KR)

(72) Inventor: In Seon YEO, Gyeonggi-do (KR)

(21) Appl. No.: 19/245,409

(22) Filed: Jun. 23, 2025

(30) Foreign Application Priority Data
Dec. 30, 2024 (KR) 10-2024-0200183

(51) Int. Cl. G11C 16/10; G11C 16/04; G11C 16/08; G11C 16/30

(52) U.S. Cl. CPC G11C 16/102; G11C 16/0466; G11C 16/08; G11C 16/30

(57) ABSTRACT

The embodiments of the present disclosure relate to a memory device including a memory cell array to store write data in at least one selected memory cell; a high voltage generator to generate a high voltage that ramps from an initial voltage level to a first voltage level during an initial period and stays at the first voltage level during a last period, the initial period being equal to or longer than the last period; a low voltage generator to generate a low voltage that ramps from the initial voltage level to a second voltage level during the initial period; a first decoder to apply one of the high voltage and the low voltage to one end of the selected memory cell; and a second decoder to apply the other one of the high voltage and the low voltage to the other end of the selected memory cell.

### CROSS-REFERENCE TO RELATED APPLICATION(S)

This application claims priority under 35 U.S.C. § 119 to Korean Patent Application No. 10-2024-0200183, filed on Dec. 30, 2024, the disclosure of which is incorporated herein by reference in its entirety.

### BACKGROUND

### 1. Field

Various embodiments of the present disclosure relate to a semiconductor design technique, and more particularly, to a memory device that supports a write mode.

### 2. Description of the Related Art

A memory device is broadly categorized into volatile memory devices and non-volatile memory devices. A volatile memory device is a memory device in which stored data is lost when the power supply is cut off. In contrast, a non-volatile memory device retains stored data even when the power supply is cut off.

A memory cell in a memory device may have a uniform logic state based on physical or chemical characteristics of a material constituting the memory cell. A non-volatile memory device that includes a memory cell formed of a chalcogenide-based material may have a slower operating speed but larger capacity or integration than a dynamic random access memory (DRAM), and a faster operating speed but smaller capacity or integration than a NAND flash memory.

### SUMMARY

Various embodiments of the present disclosure are directed to a memory device capable of suppressing a spike current that occurs in a selected memory cell during a write mode.

Various embodiments of the present disclosure are directed to a memory device capable of performing an optimal write operation according to write data during the write mode.

In accordance with an embodiment of the present disclosure, a memory device may include a memory cell array including a plurality of memory cells coupled between a plurality of first lines and a plurality of second lines and configured to store write data in at least one selected memory cell among the plurality of memory cells during a write period; a high voltage generator configured to generate a high voltage that ramps from an initial voltage level to a first target voltage level during an initial period of the write period and stays at the first target voltage level during a last period of the write period, the initial period being equal to or longer than the last period within the write period; a low voltage generator configured to generate a low voltage that ramps from the initial voltage level to a second target voltage level during the initial period and stays at the second target voltage level during the last period; a first decoder coupled to the high voltage generator, the low voltage generator and the plurality of first lines and configured to apply, based on first decoding signals, one of the high voltage and the low voltage to one end of the selected memory cell through a selected first line from the plurality of first lines during the write period; and a second decoder coupled to the high voltage generator, the low voltage generator and the plurality of second lines and configured to apply, based on second decoding signals, the other one of the high voltage and the low voltage to the other end of the selected memory cell through a selected second line from the plurality of second lines during the write period.

In accordance with an embodiment of the present disclosure, a memory device may include a memory cell array configured to store write data in at least one selected memory cell among a plurality of memory cells during a write period; a high voltage generator configured to generate, according to a logic level of the write data, a selected one of a first high voltage and a second high voltage during an initial period within the write period; a low voltage generator configured to generate, according to the logic level, a selected one of a first low voltage and a second low voltage during the initial period; a first decoder coupled to the high voltage generator, the low voltage generator and a plurality of first lines and configured to apply, based on first decoding signals, one of the selected high voltage and the selected low voltage to one end of the selected memory cell through a selected first line from the plurality of first lines during the write period; and a second decoder coupled to the high voltage generator, the low voltage generator and a plurality of second lines and configured to apply, based on second decoding signals, the other one of the selected high voltage and the selected low voltage to the other end of the selected memory cell through a selected second line from the plurality of second lines during the write period, wherein: the selected high voltage ramps from an initial voltage level to a first target voltage level during the initial period, and the selected low voltage ramps from the initial voltage level to a second target voltage level during the initial period.

In accordance with an embodiment of the present disclosure, a memory device may include a selected memory cell coupled between a selected first line and a selected second line and configured to store therein write data during one of first and second write periods; a high voltage generator configured to generate, according to a logic level of the write data, a first voltage ramping from an initial voltage level to a first target voltage level during a first initial period of a first write period and staying at the first target voltage level during a first last period of the first write period, the first voltage being a high voltage and the first initial period being equal to or longer than the first last period within the first write period; a low voltage generator configured to generate, according to the logic level, a second voltage ramping from the initial voltage level to a second target voltage level during the first initial period and staying at the second target voltage level during the first last period, the second voltage being a low voltage; a first coupling circuit configured to selectively apply the first voltage to one end of the selected memory cell through the selected first line based on a first enable signal and a first address signal; a second coupling circuit configured to selectively apply the second voltage to the one end of the selected memory cell through the selected first line based on a second enable signal and the first address signal; a third coupling circuit configured to selectively apply the first voltage to the other end of the selected memory cell through the selected second line based on the second enable signal and a second address signal; and a fourth coupling circuit configured to selectively apply the second voltage to the other end of the selected memory cell through the selected second line based on the first enable signal and the second address signal.

### BRIEF DESCRIPTION OF THE DRAWINGS

FIG. 1 is a block diagram illustrating a memory device in accordance with an embodiment of the present disclosure.

FIG. 2 is a simplified diagram illustrating a coupling structure between a memory cell array and first and second decoders illustrated in FIG. 1.

FIGS. 3 to 6 are diagrams for describing a write operation of the memory device illustrated in FIG. 1.

FIG. 7 is a block diagram illustrating a memory device in accordance with an embodiment of the present disclosure.

FIG. 8 is a simplified diagram illustrating a coupling structure between a memory cell array, a first decoder and a second decoder illustrated in FIG. 7.

FIGS. 9 to 11 are diagrams for describing a write operation of the memory device illustrated in FIG. 7.

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

It will be understood that when an element is described as being “connected to” or “coupled to” another element, the connection may be direct, or it may be indirect through one or more intervening elements, either physically or electrically. In addition, it will also be understood that the terms “comprises,” “comprising,” “includes,” and “including” when used in this specification do not preclude the presence of one or more other elements but may further include or have the one or more other elements, unless otherwise mentioned. In the description throughout the present disclosure, some components are described in singular forms, but the present disclosure is not limited thereto, and it will be understood that the components may be formed in plural.

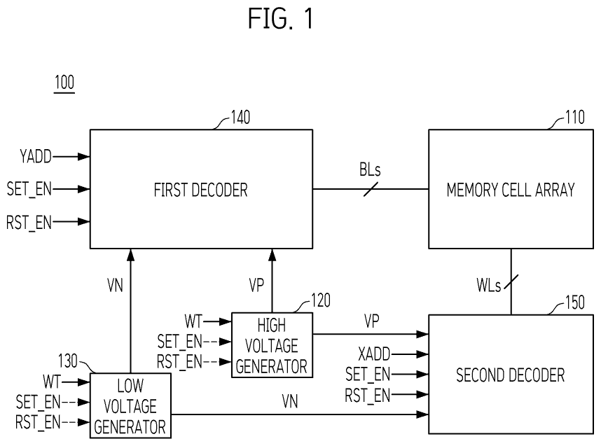

FIG. 1 is a block diagram illustrating a memory device 100 in accordance with an embodiment of the present disclosure.

Referring to FIG. 1, the memory device 100 may include a memory cell array 110, a high voltage generator 120, a low voltage generator 130, a first decoder 140, and a second decoder 150.

The memory cell array 110 may include a plurality of memory cells. The plurality of memory cells may be coupled between a plurality of bit lines BLs and a plurality of word lines WLs. For example, the plurality of memory cells may be coupled to intersections between the plurality of bit lines BLs and the plurality of word lines WLs.

The memory cell array 110 may store write data in at least one selected memory cell among the plurality of memory cells during a write mode. The memory cell array 110 may read read data from at least one selected memory cell among the plurality of memory cells during a read mode.

For example, each of the plurality of memory cells may include a selector only memory (SOM) element. The SOM element may operate as a self-selecting memory that simultaneously functions as both a memory element and a selection element. More specifically, the self-selecting memory may exhibit a variable resistance characteristic enabling it to store data by switching between different resistance states based on a voltage difference applied across a selected memory cell. The self-selecting memory may exhibit a threshold switching characteristic, wherein it blocks or substantially limits current flow through the selected memory cell when the voltage difference across the selected memory cell is less than a predetermined threshold value and allows a current flowing through the selected memory cell to increase abruptly when the voltage difference is greater than or equal to the predetermined threshold value. The predetermined threshold value may be referred to as a threshold voltage and determine whether the self-selecting memory is turned on or off.

The threshold voltage of the self-selecting memory may vary depending on a resistance state of the self-selecting memory. That is, the self-selecting memory may have different threshold voltages corresponding to its resistance states. For example, when the self-selecting memory is in a low resistance state, it may have a first threshold voltage. On the other hand, when the self-selecting memory is in a high resistance state, it may have a second threshold voltage that is different from the first threshold voltage. Accordingly, this characteristic enables the self-selecting memory to simultaneously function as both the memory element and the selection element.

For example, the self-selecting memory may include various materials, such as a diode, an ovonic threshold switching (OTS) material (e.g., a chalcogenide-based material), a mixed ionic electronic conducting (MIEC) material (e.g., a metal-containing chalcogenide-based material), a metal insulator transition (MIT) material (e.g., NbO₂ or VO₂), or a tunneling dielectric layer having a relatively wide band gap (e.g., SiO₂ or Al₂O₃). In particular, the self-selecting memory may include a material containing a plurality of trap sites capable of trapping charges, such as an OTS material.

The high voltage generator 120 may be enabled based on a write enable signal WT during the write mode. The high voltage generator 120 may generate a high voltage VP during the write mode and supply the high voltage VP to the first and second decoders 140 and 150. For example, the high voltage VP may be a positive voltage.

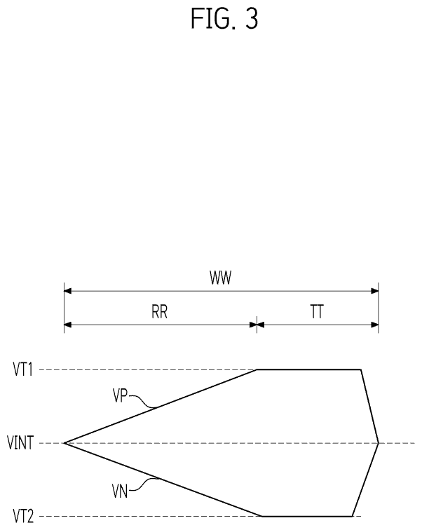

In an embodiment, the high voltage generator 120 may generate the high voltage VP having the same waveform regardless of a first enable signal SET_EN and a second enable signal RST_EN based on the write enable signal WT. The high voltage VP is described in more detail below (refer to FIG. 3). The first enable signal SET_EN may be an enable signal that is activated during the write mode when the write data has a logic level corresponding to the low resistance state. The second enable signal RST_EN may be an enable signal that is activated during the write mode when the write data has a logic level corresponding to the high resistance state.

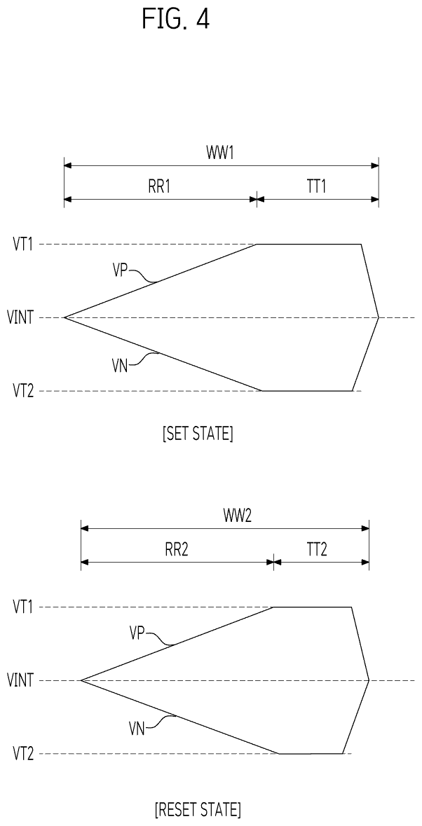

In another embodiment, the high voltage generator 120 may generate the high voltage VP having different waveforms depending on logic levels of the write data based on the write enable signal WT, the first enable signal SET_EN and the second enable signal RST_EN. The high voltage VP is described in more detail below (refer to FIG. 4).

The low voltage generator 130 may be enabled based on the write enable signal WT. The low voltage generator 130 may generate a low voltage VN during the write mode and supply the low voltage VN to the first and second decoders 140 and 150. For example, the low voltage VN may be a negative voltage.

In an embodiment, the low voltage generator 130 may generate the low voltage VN having the same waveform regardless of the first enable signal SET_EN and the second enable signal RST_EN based on the write enable signal WT. The low voltage VN is described in more detail below (refer to FIG. 3).

In another embodiment, the low voltage generator 130 may generate the low voltage VN having different waveforms depending on logic levels of the write data based on the write enable signal WT, the first enable signal SET_EN and the second enable signal RST_EN. The low voltage VN is described in more detail below (refer to FIG. 4).

The first decoder 140 may be coupled to the high voltage generator 120, the low voltage generator 130 and the plurality of bit lines BLs. The first decoder 140 may apply one of the high voltage VP and the low voltage VN to one end of the selected memory cell through a selected bit line among the plurality of bit lines BLs based on first decoding signals YADD, SET_EN and RST_EN during the write mode. For example, the first decoding signals may include a first address signal YADD, the first enable signal SET_EN, and the second enable signal RST_EN. The first address signal YADD may correspond to the selected bit line. As described above, the first enable signal SET_EN may be activated during the write mode when the write data has the logic level corresponding to the low resistance state, and the second enable signal RST_EN may be activated during the write mode when the write data has the logic level corresponding to the high resistance state.

The second decoder 150 may be coupled to the high voltage generator 120, the low voltage generator 130 and the plurality of word lines WLs. The second decoder 150 may apply the other one of the high voltage VP and the low voltage VN to the other end of the selected memory cell through a selected word line among the plurality of word lines WLs based on second decoding signals XADD, SET_EN and RST_EN during the write mode. For example, the second decoding signals may include a second address signal XADD, the first enable signal SET_EN, and the second enable signal RST_EN. The second address signal XADD may correspond to the selected word line.

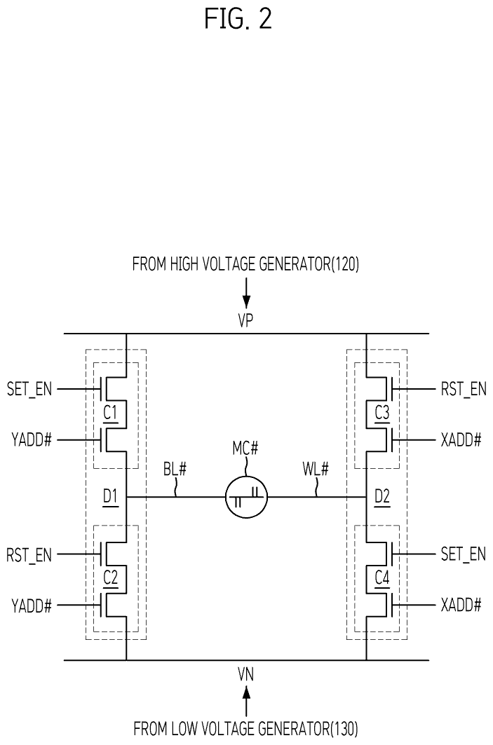

FIG. 2 is a simplified diagram illustrating a coupling structure between the memory cell array 110 and the first and second decoders 140 and 150 illustrated in FIG. 1. For example, FIG. 2 representatively illustrates only the coupling structure between a memory cell MC #among the plurality of memory cells included in the memory cell array 110, a first decoding circuit D1 among a plurality of first decoding circuits included in the first decoder 140 and a second decoding circuit D2 among a plurality of second decoding circuits included in the second decoder 150.

The memory cell MC #may include the SOM element. The memory cell MC #may be coupled between a bit line BL #and a word line WL #.

The first decoding circuit D1 may be coupled to the bit line BL #. The first decoding circuit D1 may apply one of the high voltage VP and the low voltage VN to one end of the memory cell MC #through the bit line BL #based on a first address signal YADD #, the first enable signal SET_EN and the second enable signal RST_EN. The first address signal YADD #may represent the bit line BL #and be a signal obtained by decoding the first address signal YADD. For example, the first decoding circuit D1 may include a first coupling circuit C1 and a second coupling circuit C2.

The first coupling circuit C1 may be coupled between the high voltage generator 120 and the bit line BL #. The first coupling circuit C1 may selectively couple the high voltage generator 120 to the bit line BL #based on the first enable signal SET_EN and the first address signal YADD #. For example, the first coupling circuit C1 may electrically couple the high voltage generator 120 to the bit line BL #when the write data has the logic level corresponding to the low resistance state during the write mode. Alternatively, the first coupling circuit C1 may electrically decouple the high voltage generator 120 from the bit line BL #when the write data has the logic level corresponding to the high resistance state during the write mode.

The second coupling circuit C2 may be coupled between the low voltage generator 130 and the bit line BL #. The second coupling circuit C2 may selectively couple the low voltage generator 130 to the bit line BL #based on the second enable signal RST_EN and the first address signal YADD #. For example, the second coupling circuit C2 may electrically couple the low voltage generator 130 to the bit line BL #when the write data has the logic level corresponding to the high resistance state during the write mode. Alternatively, the second coupling circuit C2 may electrically decouple the low voltage generator 130 from the bit line BL #when the write data has the logic level corresponding to the low resistance state during the write mode.

The second decoding circuit D2 may be coupled to the word line WL #. The second decoding circuit D2 may apply the other one of the high voltage VP and the low voltage VN to the other end of the memory cell MC #through the word line WL #based on a second address signal XADD #, the first enable signal SET_EN and the second enable signal RST_EN. The second address signal XADD #may represent the word line WL #and be a signal obtained by decoding the second address signal XADD. For example, the second decoding circuit D2 may include a third coupling circuit C3 and a fourth coupling circuit C4.

The third coupling circuit C3 may be coupled between the high voltage generator 120 and the word line WL #. The third coupling circuit C3 may selectively couple the high voltage generator 120 to the word line WL #based on the second enable signal RST_EN and the second address signal XADD #. For example, the third coupling circuit C3 may electrically couple the high voltage generator 120 to the word line WL #when the write data has the logic level corresponding to the high resistance state during the write mode. Alternatively, the third coupling circuit C3 may electrically decouple the high voltage generator 120 from the word line WL #when the write data has the logic level corresponding to the low resistance state during the write mode.

The fourth coupling circuit C4 may be coupled between the low voltage generator 130 and the word line WL #. The fourth coupling circuit C4 may selectively couple the low voltage generator 130 to the word line WL #based on the first enable signal SET_EN and the second address signal XADD #. For example, the fourth coupling circuit C4 may electrically couple the low voltage generator 130 to the word line WL #when the write data has the logic level corresponding to the low resistance state during the write mode. Alternatively, the fourth coupling circuit C4 may electrically decouple the low voltage generator 130 from the word line WL #when the write data has the logic level corresponding to the high resistance state during the write mode.

Hereinafter, the write operation of the memory device 100, which has the above-described configuration illustrated in FIGS. 1 and 2, is described with reference to FIGS. 3 to 6.

FIG. 3 is a graph diagram illustrating the operations of the high voltage generator 120 and the low voltage generator 130 included in the memory device 100 illustrated in FIG. 1.

Referring to FIG. 3, the high voltage generator 120 may generate the high voltage VP having the same waveform regardless of the first enable signal SET_EN and the second enable signal RST_EN based on the write enable signal WT. The high voltage generator 120 may generate the high voltage VP having a predetermined waveform regardless of the logic levels of the write data during a write period WW. For example, the high voltage VP may ramp up from an initial voltage level VINT to a first target voltage level VT1 during an initial period RR and stay at the first target voltage level VT1 during a last period TT. More precisely, the high voltage VP may stay at the first target voltage level VT1 and then be initialized to the initial voltage level VINT during the last period TT.

The low voltage generator 130 may generate the low voltage VN having the same waveform regardless of the first enable signal SET_EN and the second enable signal RST_EN based on the write enable signal WT. The low voltage generator 130 may generate the low voltage VN having a predetermined waveform regardless of the logic levels of the write data during the write period WW. For example, the low voltage VN may ramp down from the initial voltage level VINT to a second target voltage level VT2 during the initial period RR and stay at the second target voltage level VT2 during the last period TT. More precisely, the low voltage VN may stay at the second target voltage level VT2 and then be initialized to the initial voltage level VINT during the last period TT.

In particular, the initial period RR may be set to be equal to or longer than the last period TT within the write period WW. That is, the high voltage VP may be designed to slowly ramp up during the initial period RR corresponding to a half or longer period within the write period WW, and the low voltage VN may be designed to slowly ramp down during the initial period RR corresponding to a half or longer period within the write period WW. The slowly ramping high voltage VP and low voltage VN may be used so that a spike current occurring when the selected memory cell is turned on during the write mode may be suppressed.

FIG. 4 is a graph diagram illustrating another embodiment of the operations of the high voltage generator 120 and the low voltage generator 130 included in the memory device 100 illustrated in FIG. 1.

Referring to FIG. 4, the high voltage generator 120 may generate the high voltage VP having different waveforms depending on the logic levels of the write data based on the write enable signal WT, the first enable signal SET_EN and the second enable signal RST_EN.

The high voltage generator 120 may generate the high voltage VP having a first waveform during a first write period WW1 when the write data has the logic level corresponding to the low resistance state (i.e., a SET state). For example, the high voltage VP may ramp up from an initial voltage level VINT to a first target voltage level VT1 during a first initial period RR1 and stay at the first target voltage level VT1 during a first last period TT1. More precisely, the high voltage VP may stay at the first target voltage level VT1 and then be initialized to the initial voltage level VINT during the first last period TT1.

The low voltage generator 130 may generate the low voltage VN having a first waveform during the first write period WW1 when the write data has the logic level corresponding to the low resistance state (i.e., the SET state). For example, the low voltage VN may ramp down from the initial voltage level VINT to a second target voltage level VT2 during the first initial period RR1 and stay at the second target voltage level VT2 during the first last period TT1. More precisely, the low voltage VN may stay at the second target voltage level VT2 and then be initialized to the initial voltage level VINT during the first last period TT1.

In particular, the first initial period RR1 may be set to be equal to or longer than the first last period TT1 within the first write period WW1. That is, the high voltage VP may be designed to slowly ramp up during the first initial period RR1 corresponding to a half or longer period within the first write period WW1, and the low voltage VN may be designed to slowly ramp down during the first initial period RR1 corresponding to a half or longer period within the first write period WW1. The slowly ramping high voltage VP and low voltage VN may be used so that a spike current occurring when the selected memory cell is turned on during the write mode may be suppressed.

The high voltage generator 120 may generate the high voltage VP having a second waveform during a second write period WW2 when the write data has the logic level corresponding to the high resistance state (i.e., a RESET state). For example, the high voltage VP may ramp up from the initial voltage level VINT to the first target voltage level VT1 during a second initial period RR2 and stay at the first target voltage level VT1 during a second last period TT2. More precisely, the high voltage VP may stay at the first target voltage level VT1 and then be initialized to the initial voltage level VINT during the second last period TT2.

The low voltage generator 130 may generate the low voltage VN having a second waveform during the second write period WW2 when the write data has the logic level corresponding to the high resistance state (i.e., the RESET state). For example, the low voltage VN may ramp down from the initial voltage level VINT to a second target voltage level VT2 during the second initial period RR2 and stay at the second target voltage level VT2 during the second last period TT2. More precisely, the low voltage VN may stay at the second target voltage level VT2 and then be initialized to the initial voltage level VINT during the second last period TT2.

In particular, the second initial period RR2 may be set to be longer than the second last period TT2 within the second write period WW2. That is, the high voltage VP may be designed to slowly ramp up during the second initial period RR2 corresponding to a longer period than a half of the second write period WW2, and the low voltage VN may be designed to slowly ramp down during the second initial period RR2 corresponding to a longer period than a half of the second write period WW2. The slowly ramping high voltage VP and low voltage VN may be used so that a spike current occurring when the selected memory cell is turned on during the write mode may be suppressed.

The first initial period RR1 may be the same as the second initial period RR2. The first last period TT1 may be longer than the second last period TT2. The second last period TT2 may be shorter than the first last period TT1. Accordingly, the second write period WW2 may be shorter than the first write period WW1. When the write data having a logic level corresponding to the low resistance state is stored in the selected memory cell, the longer the first last period TT1 is (that is, the longer a period in which the high and low voltages VP and VN stay at the respective first and second target voltage levels VT1 and VT2), the lower the threshold voltage of the selected memory cell may be formed. When the write data having a logic level corresponding to the high resistance state is stored in the selected memory cell, the shorter the second last period TT2 is (that is, the shorter the period in which the high and low voltages VP and VN stay at the respective first and second target voltage levels VT1 and VT2), the higher the threshold voltage of the selected memory cell may be formed. The high voltage VP and low voltage VN to which different last periods (TT1 or TT2) are applied depending on the logic levels of the write data during the write mode may be used, which makes it possible to sufficiently secure a read window margin during a read mode subsequent to the write mode.

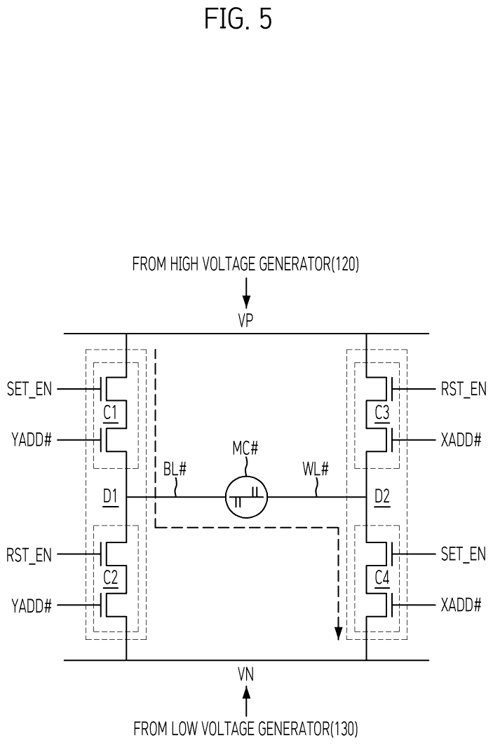

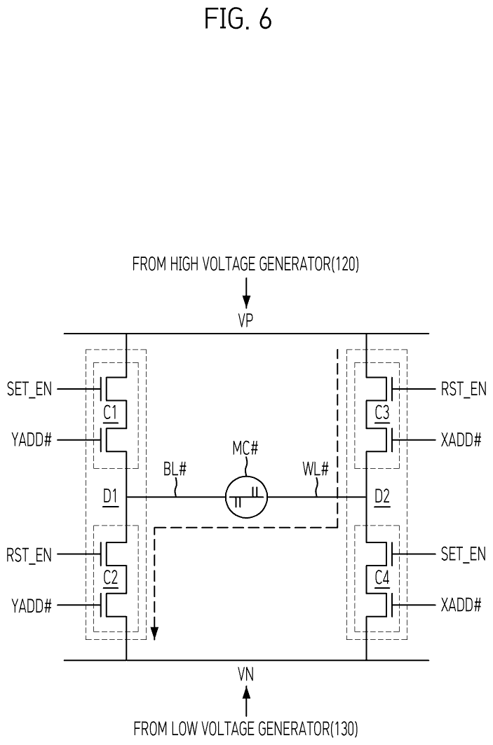

FIG. 5 is a simplified diagram for describing an operation in which the write data having a logic level corresponding to the low resistance state is stored in the selected memory cell among the plurality of memory cells included in the memory cell array 110 illustrated in FIG. 1. FIG. 6 is a simplified diagram for describing an operation in which the write data having a logic level corresponding to the high resistance state is stored in the selected memory cell among the plurality of memory cells included in the memory cell array 110 illustrated in FIG. 1. For example, FIGS. 5 and 6 are simplified diagrams based on FIG. 2. Hereinafter, the bit line BL #, the word line WL #and the memory cell MC #illustrated in FIGS. 5 and 6 are referred to as the selected bit line, the selected word line and the selected memory cell, respectively.

Referring to FIG. 5, when the write data has the logic level corresponding to the low resistance state, the first enable signal SET_EN may be activated during the write mode, and the second enable signal RESET_EN may be deactivated during the write mode. Accordingly, the first coupling circuit C1 and the fourth coupling circuit C4 may be enabled during the write mode, and the second coupling circuit C2 and the third coupling circuit C3 may be disabled during the write mode.

The first coupling circuit C1 may apply the high voltage VP to one end of the selected memory cell MC #through the selected bit line BL #, and the fourth coupling circuit C4 may apply the low voltage VN to the other end of the selected memory cell MC #through the selected word line WL #. Accordingly, a cell current may flow through a supply end of the high voltage VP, the first coupling circuit C1, the selected bit line BL #, the selected memory cell MC #, the fourth coupling circuit C4 and a supply end of the low voltage VN. That is, the cell current may flow from the one end to the other end of the selected memory cell MC #along the arrow illustrated in FIG. 5. The selected memory cell MC #may be in the low resistance state, i.e., the SET state, depending on the direction of the cell current.

Referring to FIG. 6, when the write data has the logic level corresponding to the high resistance state, the second enable signal RESET_EN may be activated during the write mode, and the first enable signal SET_EN may be deactivated during the write mode. Accordingly, the second coupling circuit C2 and the third coupling circuit C3 may be enabled during the write mode, and the first coupling circuit C1 and the fourth coupling circuit C4 may be disabled during the write mode.

The third coupling circuit C3 may apply the high voltage VP to the other end of the selected memory cell MC #through the selected word line WL #, and the second coupling circuit C2 may apply the low voltage VN to the one end of the selected memory cell MC #through the selected bit line BL #. Accordingly, a cell current may flow through a supply end of the high voltage VP, the third coupling circuit C3, the selected word line WL #, the selected memory cell MC #, the second coupling circuit C2 and a supply end of the low voltage VN. That is, the cell current may flow from the other end to the one end of the selected memory cell MC #along the arrow illustrated in FIG. 6. The selected memory cell MC #may be in the high resistance state, i.e., the RESET state, depending on the direction of the cell current.

According to an embodiment of the present disclosure, the high voltage VP and the low voltage VN that slowly ramp during the write mode may be used, which makes it possible to suppress the spike current that occurs when the selected memory cell MC #is turned on. In addition, the high voltage VP and the low voltage VN each having different waveforms depending on the logic levels of the write data may be used, which makes it possible to perform an optimal write operation.

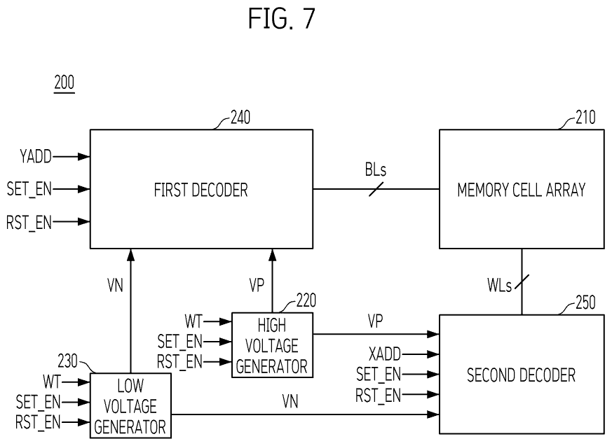

FIG. 7 is a block diagram illustrating a memory device 200 in accordance with an embodiment of the present disclosure.

Referring to FIG. 7, the memory device 200 may include a memory cell array 210, a high voltage generator 220, a low voltage generator 230, a first decoder 240, and a second decoder 250.

The memory cell array 210 may include a plurality of memory cells. The plurality of memory cells may be coupled between a plurality of bit lines BLs and a plurality of word lines WLs. For example, the plurality of memory cells may be coupled to intersections between the plurality of bit lines BLs and the plurality of word lines WLs.

The memory cell array 210 may store write data in at least one selected memory cell among the plurality of memory cells during a write mode. The memory cell array 210 may read read data from at least one selected memory cell among the plurality of memory cells during a read mode.

For example, each of the plurality of memory cells may include a selector only memory (SOM) element. The SOM element may operate as a self-selecting memory that simultaneously functions as both a memory element and a selection element. More specifically, the self-selecting memory may exhibit a variable resistance characteristic enabling it to store data by switching between different resistance states based on a voltage difference applied across both ends of a selected memory cell. The self-selecting memory may exhibit a threshold switching characteristic, wherein it blocks or substantially limits current flow through the selected memory cell when the voltage difference across the selected memory cell is less than a predetermined threshold value and allows a current flowing through the selected memory cell to increase abruptly when the voltage difference is greater than or equal to the predetermined threshold value. The predetermined threshold value may be referred to as a threshold voltage and determine whether the self-selecting memory is turned on or off.

The threshold voltage of the self-selecting memory may vary depending on a resistance state of the self-selecting memory. That is, the self-selecting memory may have different threshold voltages corresponding to its resistance states. For example, when the self-selecting memory is in a low resistance state, it may have a first threshold voltage. On the other hand, when the self-selecting memory is in a high resistance state, it may have a second threshold voltage that is different from the first threshold voltage. Accordingly, this characteristic enables the self-selecting memory to simultaneously function as both the memory element and the selection element.

For example, the self-selecting memory may include various materials, such as a diode, an ovonic threshold switching (OTS) material (e.g., a chalcogenide-based material), a mixed ionic electronic conducting (MIEC) material (e.g., a metal-containing chalcogenide-based material), a metal insulator transition (MIT) material (e.g., NbO₂ or VO₂), or a tunneling dielectric layer having a relatively wide band gap (e.g., SiO₂ or Al₂O₃). In particular, the self-selecting memory may include a material containing a plurality of trap sites capable of trapping charges, such as an OTS material.

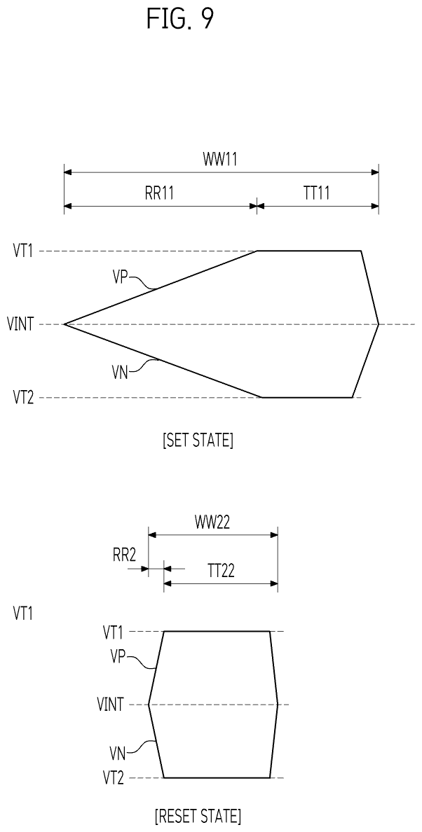

The high voltage generator 220 may be enabled based on a write enable signal WT during the write mode. The high voltage generator 220 may generate a high voltage VP having different waveforms during the write mode based on a first enable signal SET_EN and a second enable signal RESET_EN (refer to FIG. 9) and supply the high voltage VP to the first and second decoders 240 and 250. For example, the high voltage VP may be a positive voltage. The first enable signal SET_EN may be activated during the write mode when the write data has a logic level corresponding to the low resistance state. The second enable signal RST_EN may be activated during the write mode when the write data has a logic level corresponding to the high resistance state.

The low voltage generator 230 may be enabled based on the write enable signal WT. The low voltage generator 230 may generate a low voltage VN having different waveforms during the write mode based on the first enable signal SET_EN and the second enable signal RST_EN (refer to FIG. 9) and supply the low voltage VN to the first and second decoders 240 and 250. For example, the low voltage VN may be a negative voltage.

The first decoder 240 may be coupled to the high voltage generator 220, the low voltage generator 230 and the plurality of bit lines BLs. The first decoder 240 may apply one of the high voltage VP and the low voltage VN to one end of the selected memory cell through a selected bit line among the plurality of bit lines BLs based on first decoding signals YADD, SET_EN and RST_EN during the write mode. For example, the first decoding signals may include a first address signal YADD, the first enable signal SET_EN, and the second enable signal RST_EN. The first address signal YADD may correspond to the selected bit line. As described above, the first enable signal SET_EN may be activated during the write mode when the write data has the logic level corresponding to the low resistance state, and the second enable signal RST_EN may be activated during the write mode when the write data has the logic level corresponding to the high resistance state.

The second decoder 250 may be coupled to the high voltage generator 220, the low voltage generator 230 and the plurality of word lines WLs. The second decoder 250 may apply the other one of the high voltage VP and the low voltage VN to the other end of the selected memory cell through a selected word line among the plurality of word lines WLs based on second decoding signals XADD, SET_EN and RST_EN during the write mode. For example, the second decoding signals may include a second address signal XADD, the first enable signal SET_EN, and the second enable signal RST_EN. The second address signal XADD may correspond to the selected word line.

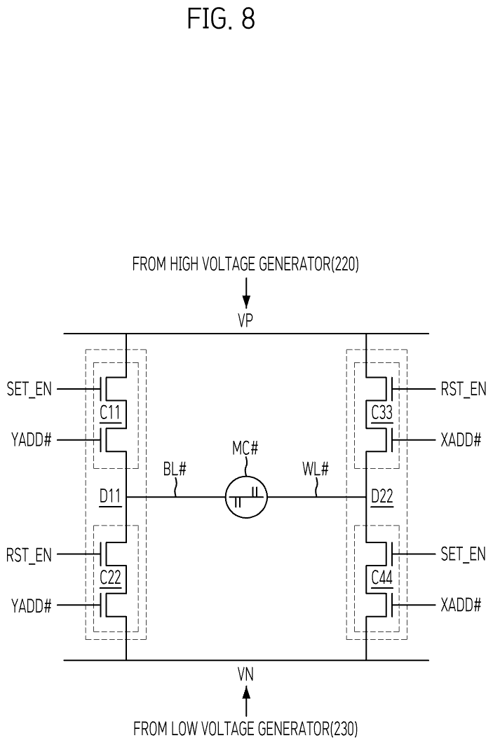

FIG. 8 is a simplified diagram illustrating a coupling structure between the memory cell array 210 and the first and second decoders 240 and 250 illustrated in FIG. 7. For example, FIG. 8 representatively illustrates only the coupling structure between a memory cell MC #among the plurality of memory cells included in the memory cell array 210, a first decoding circuit D11 among a plurality of first decoding circuits included in the first decoder 240 and a second decoding circuit D22 among a plurality of second decoding circuits included in the second decoder 250.

The memory cell MC #may include the SOM element. The memory cell MC #may be coupled between a bit line BL #and a word line WL #.

The first decoding circuit D11 may be coupled to the bit line BL #. The first decoding circuit D11 may apply one of the high voltage VP and the low voltage VN to one end of the memory cell MC #through the bit line BL #based on a first address signal YADD #, the first enable signal SET_EN and the second enable signal RST_EN. The first address signal YADD #may represent the bit line BL #and be a signal obtained by decoding the first address signal YADD. For example, the first decoding circuit D11 may include a first coupling circuit C11 and a second coupling circuit C22.

The first coupling circuit C11 may be coupled between the high voltage generator 220 and the bit line BL #. The first coupling circuit C11 may selectively couple the high voltage generator 220 to the bit line BL #based on the first enable signal SET_EN and the first address signal YADD #. For example, the first coupling circuit C11 may electrically couple the high voltage generator 220 to the bit line BL #when the write data has the logic level corresponding to the low resistance state during the write mode. Alternatively, the first coupling circuit C11 may electrically decouple the high voltage generator 220 from the bit line BL #when the write data has the logic level corresponding to the high resistance state during the write mode.

The second coupling circuit C22 may be coupled between the low voltage generator 230 and the bit line BL #. The second coupling circuit C22 may selectively couple the low voltage generator 230 to the bit line BL #based on the second enable signal RST_EN and the first address signal YADD #. For example, the second coupling circuit C22 may electrically couple the low voltage generator 230 to the bit line BL #when the write data has the logic level corresponding to the high resistance state during the write mode. Alternatively, the second coupling circuit C22 may electrically decouple the low voltage generator 230 from the bit line BL #when the write data has the logic level corresponding to the low resistance state during the write mode.

The second decoding circuit D22 may be coupled to the word line WL #. The second decoding circuit D22 may apply the other one of the high voltage VP and the low voltage VN to the other end of the memory cell MC #through the word line WL #based on a second address signal XADD #, the first enable signal SET_EN and the second enable signal RST_EN. The second address signal XADD #may represent the word line WL #and be a signal obtained by decoding the second address signal XADD. For example, the second decoding circuit D22 may include a third coupling circuit C33 and a fourth coupling circuit C44.

The third coupling circuit C33 may be coupled between the high voltage generator 220 and the word line WL #. The third coupling circuit C33 may selectively couple the high voltage generator 220 to the word line WL #based on the second enable signal RST_EN and the second address signal XADD #. For example, the third coupling circuit C33 may electrically couple the high voltage generator 220 to the word line WL #when the write data has the logic level corresponding to the high resistance state during the write mode. Alternatively, the third coupling circuit C33 may electrically decouple the high voltage generator 220 from the word line WL #when the write data has the logic level corresponding to the low resistance state during the write mode.

The fourth coupling circuit C44 may be coupled between the low voltage generator 230 and the word line WL #. The fourth coupling circuit C44 may selectively couple the low voltage generator 230 to the word line WL #based on the first enable signal SET_EN and the second address signal XADD #. For example, the fourth coupling circuit C44 may electrically couple the low voltage generator 230 to the word line WL #when the write data has the logic level corresponding to the low resistance state during the write mode. Alternatively, the fourth coupling circuit C44 may electrically decouple the low voltage generator 230 from the word line WL #when the write data has the logic level corresponding to the high resistance state during the write mode.

Hereinafter, the write operation of the memory device 200, which has the above-described configuration illustrated in FIGS. 7 and 8, is described with reference to FIGS. 9 to 11.

FIG. 9 is a graph diagram illustrating an embodiment of the operations of the high voltage generator 220 and the low voltage generator 230 included in the memory device 200 illustrated in FIG. 7.

Referring to FIG. 9, the high voltage generator 220 may generate the high voltage VP having different waveforms depending on the logic levels of the write data based on the write enable signal WT, the first enable signal SET_EN and the second enable signal RST_EN. The low voltage generator 230 may generate the low voltage VN having different waveforms depending on the logic levels of the write data based on the write enable signal WT, the first enable signal SET_EN and the second enable signal RST_EN.

First, the operations of the high voltage generator 220 and the low voltage generator 230 when the write data has the logic level corresponding to the low resistance state, i.e., a SET state, that is, when the first enable signal SET_EN is activated are described.

The high voltage generator 220 may generate the high voltage VP having a first waveform during a first write period WW11. For example, the high voltage VP may ramp up from an initial voltage level VINT to a first target voltage level VT1 during a first initial period RR11 and stay at the first target voltage level VT1 during a first last period TT11. More precisely, the high voltage VP may stay at the first target voltage level VT1 and then be initialized to the initial voltage level VINT during the first last period TT11.

The low voltage generator 230 may generate the low voltage VN having a first waveform during the first write period WW11. For example, the low voltage VN may ramp down from the initial voltage level VINT to a second target voltage level VT2 during the first initial period RR11 and stay at the second target voltage level VT2 during the first last period TT11. More precisely, the low voltage VN may stay at the second target voltage level VT2 and then be initialized to the initial voltage level VINT during the first last period TT11.

In particular, the first initial period RR11 may be set to be equal to or longer than the first last period TT11 within the first write period WW11. That is, the high voltage VP may be designed to slowly ramp up during the first initial period RR11 corresponding to a half or longer period within the first write period WW11, and the low voltage VN may be designed to slowly ramp down during the first initial period RR11 corresponding to a half or longer period within the first write period WW11. The slowly ramping high voltage VP and low voltage VN may be used so that a spike current occurring when the selected memory cell is turned on during the write mode may be suppressed.

Next, the operations of the high voltage generator 220 and the low voltage generator 230 when the write data has the logic level corresponding to the high resistance state, i.e., a RESET state, that is, when the second enable signal RST_EN is activated are described.

The high voltage generator 220 may generate the high voltage VP having a second waveform during a second write period WW22. For example, the high voltage VP may ramp up from the initial voltage level VINT to the first target voltage level VT1 during a second initial period RR22 and stay at the first target voltage level VT1 during a second last period TT22. More precisely, the high voltage VP may stay at the first target voltage level VT1 and then be initialized to the initial voltage level VINT during the second last period TT22.

The low voltage generator 230 may generate the low voltage VN having a second waveform during the second write period WW22. For example, the low voltage VN may ramp down from the initial voltage level VINT to a second target voltage level VT2 during the second initial period RR22 and stay at the second target voltage level VT2 during the second last period TT22. More precisely, the low voltage VN may stay at the second target voltage level VT2 and then be initialized to the initial voltage level VINT during the second last period TT22.

In particular, the second initial period RR22 may be set to be shorter than the second last period TT22 within the second write period WW22. That is, the high voltage VP may be designed to rapidly ramp up during the second initial period RR22 corresponding to a shorter period than a half of the second write period WW22, and the low voltage VN may be designed to rapidly ramp down during the second initial period RR22 corresponding to a shorter period than a half of the second write period WW22.

The first initial period RR11 may be longer than the second initial period RR22. The second initial period RR22 may be shorter than the first initial period RR11. The first last period TT11 may be longer than the second last period TT22. The second last period TT22 may be shorter than the first last period TT11. Accordingly, the second write period WW22 may be shorter than the first write period WW11. When the write data having a logic level corresponding to the low resistance state is stored in the selected memory cell, the longer the first last period TT11 is (that is, the longer a period in which the high and low voltages VP and VN stay at the respective first and second target voltage levels VT1 and VT2), the lower the threshold voltage of the selected memory cell may be formed. When the write data having a logic level corresponding to the high resistance state is stored in the selected memory cell, the shorter the second last period TT22 is (that is, the shorter the period in which the high and low voltages VP and VN stay at the respective first and second target voltage levels VT1 and VT2), the higher the threshold voltage of the selected memory cell may be formed. The high voltage VP and low voltage VN to which different last periods (TT11 or TT22) are applied depending on the logic levels of the write data during the write mode may be used, which makes it possible to sufficiently secure a read window margin during a read mode subsequent to the write mode.

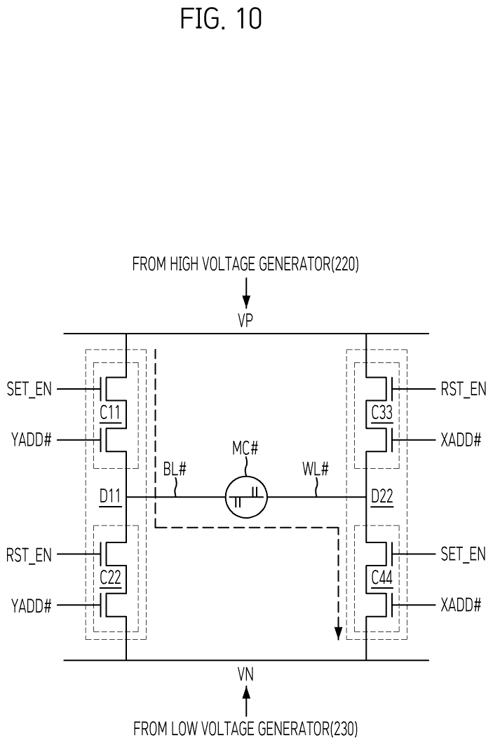

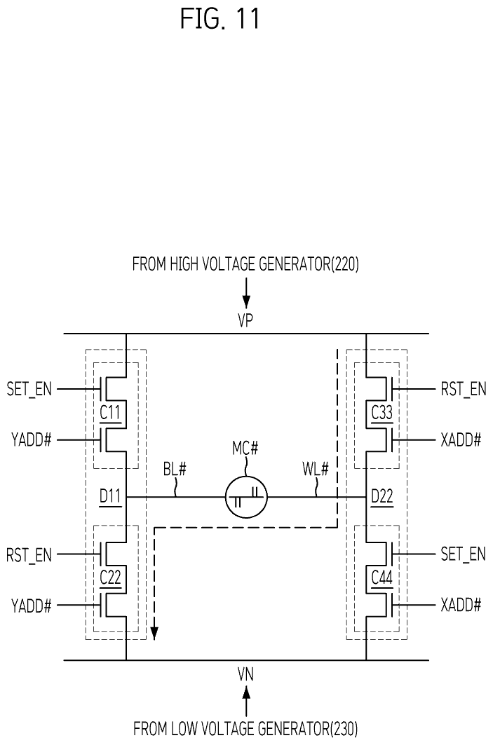

FIG. 10 is a simplified diagram for describing an operation in which the write data having a logic level corresponding to the low resistance state is stored in the selected memory cell among the plurality of memory cells included in the memory cell array 210 illustrated in FIG. 7. FIG. 11 is a simplified diagram for describing an operation in which the write data having a logic level corresponding to the high resistance state is stored in the selected memory cell among the plurality of memory cells included in the memory cell array 210 illustrated in FIG. 7. For example, FIGS. 10 and 11 are simplified diagrams based on FIG. 8. Hereinafter, the bit line BL #, the word line WL #and the memory cell MC #illustrated in FIGS. 10 and 11 are referred to as the selected bit line, the selected word line and the selected memory cell, respectively.

Referring to FIG. 10, when the write data has the logic level corresponding to the low resistance state, the first enable signal SET_EN may be activated during the write mode, and the second enable signal RESET_EN may be deactivated during the write mode. Accordingly, the first coupling circuit C11 and the fourth coupling circuit C44 may be enabled during the write mode, and the second coupling circuit C22 and the third coupling circuit C33 may be disabled during the write mode.

The first coupling circuit C11 may apply the high voltage VP to one end of the selected memory cell MC #through the selected bit line BL #, and the fourth coupling circuit C44 may apply the low voltage VN to the other end of the selected memory cell MC #through the selected word line WL #. Accordingly, a cell current may flow through a supply end of the high voltage VP, the first coupling circuit C11, the selected bit line BL #, the selected memory cell MC #, the fourth coupling circuit C44 and a supply end of the low voltage VN. That is, the cell current may flow from the one end to the other end of the selected memory cell MC #along the arrow illustrated in FIG. 10. The selected memory cell MC #may be in the low resistance state, i.e., the SET state, depending on the direction of the cell current.

Referring to FIG. 11, when the write data has the logic level corresponding to the high resistance state, the second enable signal RESET_EN may be activated during the write mode, and the first enable signal SET_EN may be deactivated during the write mode. Accordingly, the second coupling circuit C22 and the third coupling circuit C33 may be enabled during the write mode, and the first coupling circuit C11 and the fourth coupling circuit C44 may be disabled during the write mode.

The third coupling circuit C33 may apply the high voltage VP to the other end of the selected memory cell MC #through the selected word line WL #, and the second coupling circuit C22 may apply the low voltage VN to the one end of the selected memory cell MC #through the selected bit line BL #. Accordingly, a cell current may flow through a supply end of the high voltage VP, the third coupling circuit C33, the selected word line WL #, the selected memory cell MC #, the second coupling circuit C22 and a supply end of the low voltage VN. That is, the cell current may flow from the other end to the one end of the selected memory cell MC #along the arrow illustrated in FIG. 11. The selected memory cell MC #may be in the high resistance state, i.e., the RESET state, depending on the direction of the cell current.

According to an embodiment of the present disclosure, the high voltage VP and the low voltage VN that slowly ramp during the write mode may be used, which makes it possible to suppress the spike current that occurs when the selected memory cell MC #is turned on. In addition, the high voltage VP and the low voltage VN each having different waveforms depending on the logic levels of the write data may be used, which makes it possible to perform an optimal write operation.

According to embodiments of the present disclosure, a spike current that occurs in a selected memory cell during a write mode may be suppressed, thereby improving the durability or life of the memory.

According to embodiments of the present disclosure, an optimal write operation may be performed according to write data during the write mode, which makes it possible to sufficiently secure a read window margin during a read mode subsequent to the write mode.

While the technical concepts of the present disclosure have been illustrated and described with respect to specific embodiments, the disclosed embodiments are provided for the description, and not intended to be restrictive. Further, it is noted that the embodiments of the present disclosure may be achieved in various ways through substitution, change, and modification that fall within the scope of the following claims, as those skilled in the art will recognize in light of the present disclosure. The embodiments may be combined to form additional embodiments.

What is claimed is:

1. A memory device comprising:
a memory cell array including a plurality of memory cells coupled between a plurality of first lines and a plurality of second lines and configured to store write data in at least one selected memory cell among the plurality of memory cells during a write period;
a high voltage generator configured to generate a high voltage that ramps from an initial voltage level to a first target voltage level during an initial period of the write period and stays at the first target voltage level during a last period of the write period, the initial period being equal to or longer than the last period within the write period;
a low voltage generator configured to generate a low voltage that ramps from the initial voltage level to a second target voltage level during the initial period and stays at the second target voltage level during the last period;
a first decoder coupled to the high voltage generator, the low voltage generator and the plurality of first lines and configured to apply, based on first decoding signals, one of the high voltage and the low voltage to one end of the selected memory cell through a selected first line from the plurality of first lines during the write period; and
a second decoder coupled to the high voltage generator, the low voltage generator and the plurality of second lines and configured to apply, based on second decoding signals, the other one of the high voltage and the low voltage to the other end of the selected memory cell through a selected second line from the plurality of second lines during the write period.

2. The memory device of claim 1, wherein the first decoder includes:
a first coupling circuit coupled between the high voltage generator and the selected first line and configured to selectively couple the high voltage generator to the selected first line based on a first enable signal and a first address signal; and
a second coupling circuit coupled between the low voltage generator and the selected first line and configured to selectively couple the low voltage generator to the selected first line based on a second enable signal and the first address signal.

3. The memory device of claim 2, wherein the second decoder includes:
a third coupling circuit coupled between the high voltage generator and the selected second line and configured to selectively couple the high voltage generator to the selected second line based on the second enable signal and a second address signal; and
a fourth coupling circuit coupled between the low voltage generator and the selected second line and configured to selectively couple the low voltage generator to the selected second line based on the first enable signal and the second address signal.

4. The memory device of claim 1, wherein the first decoder applies the high voltage to the selected first line when the write data has a logic level corresponding to a low resistance state and applies the low voltage to the selected first line when the write data has a logic level corresponding to a high resistance state.

5. The memory device of claim 4, wherein the second decoder applies the low voltage to the selected second line when the write data has the logic level corresponding to the low resistance state and applies the high voltage to the selected second line when the write data has the logic level corresponding to the high resistance state.

6. The memory device of claim 1, wherein:
the first decoding signals include a first enable signal corresponding to the write data in a low resistance state and a first address signal corresponding to the selected first line, and
the second decoding signals include a second enable signal corresponding to the write data in a high resistance state and a second address signal corresponding to the selected second line.

7. The memory device of claim 1, wherein:
the high voltage includes a positive voltage, and
the low voltage includes a negative voltage.

8. A memory device comprising:
a memory cell array configured to store write data in at least one selected memory cell among a plurality of memory cells during a write period;
a high voltage generator configured to generate, according to a logic level of the write data, a selected one of a first high voltage and a second high voltage during an initial period within the write period;
a low voltage generator configured to generate, according to the logic level, a selected one of a first low voltage and a second low voltage during the initial period;
a first decoder coupled to the high voltage generator, the low voltage generator and a plurality of first lines and configured to apply, based on first decoding signals, one of the selected high voltage and the selected low voltage to one end of the selected memory cell through a selected first line from the plurality of first lines during the write period; and
a second decoder coupled to the high voltage generator, the low voltage generator and a plurality of second lines and configured to apply, based on second decoding signals, the other one of the selected high voltage and the selected low voltage to the other end of the selected memory cell through a selected second line from the plurality of second lines during the write period, wherein:
the selected high voltage ramps from an initial voltage level to a first target voltage level during the initial period, and
the selected low voltage ramps from the initial voltage level to a second target voltage level during the initial period.

9. The memory device of claim 8, wherein the first decoder includes:
a first coupling circuit coupled between the high voltage generator and the selected first line and configured to selectively couple the high voltage generator to the selected first line based on a first enable signal and a first address signal; and
a second coupling circuit coupled between the low voltage generator and the selected first line and configured to selectively couple the low voltage generator to the selected first line based on a second enable signal and the first address signal.

10. The memory device of claim 9, wherein the second decoder includes:
a third coupling circuit coupled between the high voltage generator and the selected second line and configured to selectively couple the high voltage generator to the selected second line based on the second enable signal and a second address signal; and
a fourth coupling circuit coupled between the low voltage generator and the selected second line and configured to selectively couple the low voltage generator to the selected second line based on the first enable signal and the second address signal.

11. The memory device of claim 8, wherein:
the high voltage generator generates the first high voltage during the initial period, which is relatively long, when the logic level corresponds to a low resistance state, and
the high voltage generator generates the second high voltage during the initial period, which is relatively short, when the logic level corresponds to a high resistance state.

12. The memory device of claim 8, wherein:
the low voltage generator generates the first low voltage during the initial period, which is relatively long, when the logic level corresponds to a low resistance state, and
the low voltage generator generates the second low voltage during the initial period, which is relatively short, when the logic level corresponds to a high resistance state.

13. The memory device of claim 8, wherein:
the high voltage generator is further configured to generate, according to the logic level, the selected high voltage during a last period within the write period,
the low voltage generator is further configured to generate, according to the logic level, the selected low voltage during the last period,
the selected high voltage stays at the first target voltage level during the last period, and
the selected low voltage stays at the second target voltage level during the last period.

14. The memory device of claim 13, wherein:
the high voltage generator generates the first high voltage during the last period, which is relatively long, when the logic level corresponds to a low resistance state, and
the high voltage generator generates the second high voltage during the last period, which is relatively short, when the logic level corresponds to a high resistance state.

15. The memory device of claim 13, wherein:
the low voltage generator generates the first low voltage during the last period, which is relatively long, when the logic level corresponds to a low resistance state, and
the low voltage generator generates the second low voltage during the last period, which is relatively short, when the logic level corresponds to a high resistance state.

16. The memory device of claim 8, wherein:
each of the first and second high voltages includes a positive voltage, and
each of the first and second low voltages includes a negative voltage.

17. A memory device comprising:
a selected memory cell coupled between a selected first line and a selected second line and configured to store therein write data during one of first and second write periods;
a high voltage generator configured to generate, according to a logic level of the write data, a first voltage ramping from an initial voltage level to a first target voltage level during a first initial period of a first write period and staying at the first target voltage level during a first last period of the first write period, the first voltage being a high voltage and the first initial period being equal to or longer than the first last period within the first write period;
a low voltage generator configured to generate, according to the logic level, a second voltage ramping from the initial voltage level to a second target voltage level during the first initial period and staying at the second target voltage level during the first last period, the second voltage being a low voltage;
a first coupling circuit configured to selectively apply the first voltage to one end of the selected memory cell through the selected first line based on a first enable signal and a first address signal;
a second coupling circuit configured to selectively apply the second voltage to the one end of the selected memory cell through the selected first line based on a second enable signal and the first address signal;
a third coupling circuit configured to selectively apply the first voltage to the other end of the selected memory cell through the selected second line based on the second enable signal and a second address signal; and
a fourth coupling circuit configured to selectively apply the second voltage to the other end of the selected memory cell through the selected second line based on the first enable signal and the second address signal.

18. The memory device of claim 17, wherein:
the first enable signal is activated when the logic level corresponds to a low resistance state, and
the second enable signal is activated when the logic level corresponds to a high resistance state.

19. The memory device of claim 17, wherein the high voltage generator generates the first voltage during the first write period when the first enable signal is activated, and
the low voltage generator generates the second voltage during the first write period when the first enable signal is activated.

20. The memory device of claim 19, wherein:
the high voltage generator is further configured to generate, according to the logic level, a third voltage ramping from the initial voltage level to the first target voltage level during a second initial period a second write period and staying at the first target voltage level during a second last period of the second write period when the second enable signal is activated, the third voltage being the high voltage and the second initial period being shorter than the second last period within the second write period, and
the low voltage generator is further configured to generate, according to the logic level, a fourth voltage ramping from the initial voltage level to the second target voltage level during the second initial period and staying at the second target voltage level during the second last period when the second enable signal is activated, the fourth voltage being the low voltage.
